(19) United States
(12) Patent Application Publication
(10) Pub. No.: US 2014/0049298 A1
(43) Pub. Date: Feb. 20, 2014

(54) FREQUENCY GENERATION APPARATUS AND FREQUENCY GENERATION METHOD

(71) Applicant: SAMSUNG ELECTRO-MECHANICS CO., LTD., Gyunggi-do (KR)

(72) Inventors: Joon Hyung LIM, Gyunggi-do (KR); Koon Shik CHO, Gyunggi-do (KR); Tah Joon PARK, Gyunggi-do (KR)

(73) Assignee: SAMSUNG ELECTRO-MECHANICS CO., LTD., Gyunggi-do (KR)

(21) Appl. No.: 13/665,292

(22) Filed: Oct. 31, 2012

(30) Foreign Application Priority Data
Aug. 14, 2012 (KR) 10-2012-0089075

(51) Int. Cl. H03B 28/00

(52) U.S. Cl. CPC H03B 28/00
USPC 327/113

(57) ABSTRACT

There are provided a frequency generation apparatus and a frequency generation method. The frequency generation apparatus includes a current generation unit varying an amount of current with respect to a temperature change; a capacitor in which charges are charged by the current generation unit; a discharge circuit unit comparing a charging voltage of the capacitor with a previously set first reference voltage and discharging the capacitor; and an output signal generation unit comparing the charging voltage of the capacitor with a previously set second reference voltage and generating an output signal, wherein the current generation unit varies the amount of current so as to maintain a constant frequency.

### CROSS-REFERENCE TO RELATED APPLICATIONS

This application claims the priority of Korean Patent Application No. 2012-0089075 filed on Aug. 14, 2012, in the Korean Intellectual Property Office, the disclosure of which is incorporated herein by reference.

### BACKGROUND OF THE INVENTION

1. Field of the Invention

The present invention relates to a frequency generation apparatus and a frequency generation method that generate a constant frequency in spite of a temperature change.

2. Description of the Related Art

A frequency generation apparatus refers to an apparatus for generating a frequency corresponding to an input voltage. However, the frequency generation apparatus may cause problematic variations in frequency due to a temperature change.

To solve this defect, a frequency of the frequency generation apparatus that varies with respect to the temperature change may remain constant by using a crystal oscillator or a structure including a temperature detection sensor and a phase locked loop (PLL). However, since the crystal oscillator does not apply a crystal vibrator to a semiconductor process such as a CMOS process, the crystal oscillator cannot be implemented in an integrated circuit (IC). Also, since the structure including the temperature detection sensor requires an analog-to-digital converter (ADC), a temperature sensor, or the like, the overall size and volume of the IC increase and a unit cost increases. Also, since the PLL needs a phase difference detector, a charge pump, a loop filter, or the like, like the structure including the temperature detection sensor, the overall size and volume of the IC may be increased as well as a unit cost thereof. Thus, a frequency generation apparatus for generating a constant frequency in spite of a temperature change without an additional circuit and device is needed.

The Related Art Document below relates to a voltage-frequency conversion apparatus and a reference voltage changing method of the voltage-frequency conversion apparatus. The invention of the following Related Art Document is problematically limited to a frequency of a ring oscillator, and only uses a current source having an amount of current decreasing according to a temperature in order to complement a frequency varying according to a temperature change.

### RELATED ART DOCUMENT

Korean Patent Laid-Open Publication No. 10-2006-0085185

### SUMMARY OF THE INVENTION

An aspect of the present invention provides a frequency generation apparatus and a frequency generation method capable of generating a constant frequency, by complementing a frequency variation in which a frequency rises or falls with respect to a temperature change by using a current source having an amount of current varying with respect to the temperature change.

Another aspect of the present invention provides a frequency generation apparatus and a frequency generation method capable of generating a constant frequency in spite of a temperature change without an additional circuit and device.

According to an aspect of the present invention, there is provided a frequency generation apparatus including: a current generation unit varying an amount of current with respect to a temperature change; a capacitor in which charges are charged by the current generation unit; a discharge circuit unit comparing a charging voltage of the capacitor with a previously set first reference voltage and discharging the capacitor; and an output signal generation unit comparing the charging voltage of the capacitor with a previously set second reference voltage and generating an output signal, wherein the current generation unit varies the amount of current so as to maintain a constant frequency in the output signal.

The current generation unit may vary the amount of current with respect to the temperature change so as to complement a frequency variation in a case in which a frequency of the output signal varies with respect to the temperature change.

The current generation unit may increase the amount of current according to a temperature rise so as to complement the frequency variation in a case in which the frequency of the output signal decreases according to the temperature rise.

The current generation unit may decrease the amount of current according to the temperature rise so as to complement the frequency variation in a case in which the frequency of the output signal increases according to the temperature rise.

The current generation unit may include: an operating amplifier including a non-inversion terminal to which a previously set third reference voltage is applied and an inversion terminal to which a feedback voltage is applied; a feedback resistor connected between the inversion terminal and a ground and detecting the feedback voltage; a current induction unit inducing current flowing through the feedback resistor to a first terminal; and a current mirroring unit mirroring the current flowing through the first terminal.

The current induction unit may be an NMOS transistor including: a gate terminal connected to an output terminal of the operating amplifier; a source terminal connected to the inversion terminal of the operating amplifier; and a drain terminal connected to the current mirroring unit.

A resistance value of the feedback resistor may vary with respect to temperature.

The feedback resistor may include one of a Poly resistor having a resistance value decreasing according to the temperature rise and an Nwell resistor having a resistance value increasing according to the temperature rise.

The third reference voltage may maintain a uniform voltage value in spite of the temperature change.

According to another aspect of the present invention, there is provided a frequency generation method including: generating a triangular wave by a current generation unit charging a capacitor and a discharge circuit unit discharging the capacitor; comparing the triangular wave with a previously set second reference voltage and generating an output signal; and varying an amount of current of the current generation unit so as to maintain a constant frequency in the output signal.

In the varying of the amount of current, the amount of current may vary with respect to a temperature change so as to complement a frequency variation in a case in which the frequency of the output signal varies with respect to the temperature change.

In the varying of the amount of current, the amount of current may increase according to a temperature rise so as to complement the frequency variation in a case in which the frequency of the output signal decreases according to the temperature rise.

In the varying of the amount of current, the amount of current may decrease according to the temperature rise so as to complement the frequency variation in a case in which the frequency of the output signal increases according to the temperature rise.

In the varying of the amount of current, an amount of the current flowing through a feedback resistor to which a previously set third reference voltage is applied may vary with respect to temperature.

A resistance value of the feedback resistor may vary with respect to the temperature.

The feedback resistor may include one of a Poly resistor having a resistance value decreasing according to the temperature rise and an Nwell resistor having a resistance value increasing according to the temperature rise.

The third reference voltage may maintain a uniform voltage value in spite of the temperature change.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a circuit diagram of a frequency generation apparatus according to an embodiment of the present invention;

FIG. 2 is a graph for explaining generation of a frequency according to an embodiment of the present invention;

FIG. 3 is a detailed circuit diagram of a current generation unit according to an embodiment of the present invention;

FIGS. 4A through 5C are graphs for explaining a frequency generation method performed by a frequency generation apparatus according to embodiments of the present invention; and

FIGS. 6 through 8 are graphs of simulation results of a frequency generation apparatus according to embodiments of the present invention.

### DETAILED DESCRIPTION OF THE EMBODIMENTS

Hereinafter, embodiments of the present invention will be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art.

In the drawings, the shapes and dimensions of elements may be exaggerated for clarity, and the same reference numerals will be used throughout to designate the same or like elements.

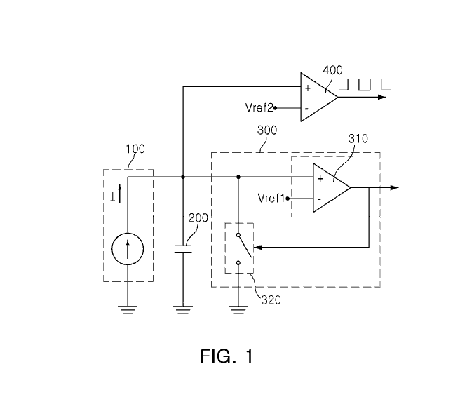

FIG. 1 is a circuit diagram of a frequency generation apparatus according to an embodiment of the present invention.

Referring to FIG. 1, the frequency generation apparatus according to an embodiment of the present invention may include a current generation unit 100, a capacitor 200, a discharge circuit unit 300, and an output signal generation unit 400. The discharge circuit unit 300 may include a comparator 310 that compares a previously set first reference voltage Vref1 and a charging voltage of the capacitor 200, and a switch 320 that switches on or off according to a result of comparison of the comparator 310.

An operation of the frequency generation apparatus according to an embodiment of the present invention will now be described assuming that the switch 320 is initially in an off state.

A current generated by the current generation unit 100 may flow to the capacitor 200 and charge the capacitor 200 with charges. In this regard, a charging speed of charges is determined by an amount of the current generated by the current generation unit 100. In a case in which a large amount of current is generated by the current generation unit 100, an inclination per unit time of a charging voltage by the charges charged in the capacitor 200 is steep. In a case in which a small amount of current is generated by the current generation unit 100, an inclination per unit time of the charging voltage by the charges charged in the capacitor 200 is gentle.

The comparator 310 may compare the charging voltage with charges charged in the capacitor 200, with the previously set first reference voltage Vref1. More specifically, the comparator 310 may include an operating amplifier having a non-inversion terminal to which the charging voltage of the capacitor 200 is applied and an inversion terminal to which the previously set first reference voltage Vref1 is applied.

In results of comparing the charging voltage of the capacitor 200 with the first reference voltage, in a case in which the charging voltage of the capacitor 200 is higher than the previously set first reference voltage Vref1, the comparator 310 outputs a high signal. In a case in which the charging voltage of the capacitor 200 is lower than the previously set first reference voltage Vref1, the comparator 310 outputs a low signal. The previously set first reference voltage Vref1 may be set to be lower than a maximum charging voltage of the capacitor 200.

The switch 320 may operate in an on state in a case in which the comparator 310 outputs the high signal in the comparison results, and may operate in an off state in a case in which the comparator 310 outputs the low signal in the comparison results. In a case in which the switch 320 is in an on state, the charges charged in the capacitor 200 are discharged so that a level of the charging voltage of the capacitor 200 decreases. In a case in which the switch 320 is in an off state, the capacitor 200 is charged by the current output from the current generation unit 100 so that the level of the charging voltage of the capacitor 200 increases.

The output signal generation unit 400 compares the charging voltage of the capacitor 200 with a previously set second reference voltage Vref2 and generates an output signal. More specifically, the output signal generation unit 400 may include an operating amplifier including a non-inversion terminal to which the charging voltage of the capacitor 200 is applied and an inversion terminal to which the second reference voltage Vref2 is applied.

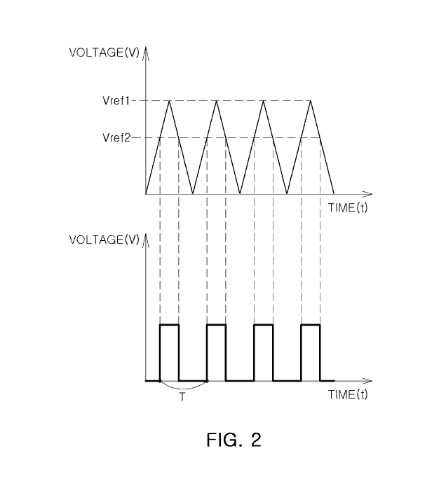

FIG. 2 is a graph for explaining the generation of a frequency according to an embodiment of the present invention. An operation of the frequency generation apparatus according to an embodiment of the present invention will now be described in more detail with reference to FIGS. 1 and 2 assuming that there is no charge initially charged in the capacitor 200 and the switch 320 connected parallel to the capacitor 200 is turned off.

Since the switch 320 is in an off state, the capacitor 200 is charged by current output from the current generation unit 100, and the charging voltage of the capacitor 200 rises at a uniform inclination.

In a case in which the charging voltage of the capacitor 200 is higher than the second reference voltage Vref2, the output signal generation unit 400 may output a high signal. In a case in which the charging voltage of the capacitor 200 further rises and is the same as the first reference voltage Vref1, the comparator 310 may output the high signal.

The comparator 310 may output the high signal HIGH in such a manner that the switch 320 operates in an on state until an electric potential of the charging voltage of the capacitor 200 falls to a level of 0, and may maintain the high signal until the electric potential of the charging voltage of the capacitor 200 is on the level of 0. Accordingly, the charging voltage of the capacitor 200 may have a triangle waveform.

As the switch 320 operates is turned on, in a case in which the charging voltage of the capacitor 200 falls below the second reference voltage Vref2, the output signal generation unit 400 may generate a low signal. In a case in which the charging voltage of the capacitor 200 further falls and the electric potential thereof is on the level of 0, the comparator 310 may output the low signal, and the switch 320 may be switched off. Charges may be charged in the capacitor 200 by the current generation unit 100 again while the switch 320 is switched off.

The capacitor 200 repeats the above-described charging and discharging operations so that the comparator 310 may output a frequency signal having a cycle T.

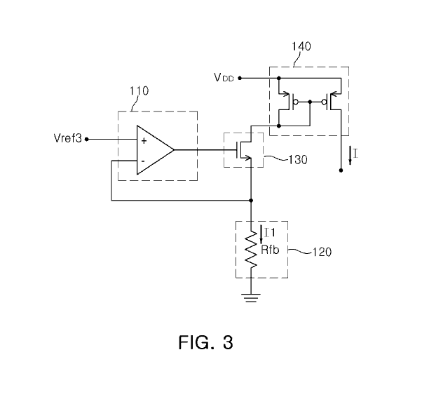

FIG. 3 is a detailed circuit diagram of the current generation unit 100 according to an embodiment of the present invention.

Referring to FIG. 3, the current generation unit 100 may include an operating amplifier 110, a feedback resistor 120, a current induction unit 130, and a current mirroring unit 140. The operating amplifier 110 may include a non-inversion terminal to which a previously set third reference voltage Vref3 is applied and an inversion terminal to which a feedback voltage is applied.

The feedback resistor 120 may be connected to the inversion terminal of the operating amplifier 110 and detect a feedback voltage. The current induction unit 130 may induce current flowing through the feedback resistor 120 to a first terminal. Also, the current mirroring unit 140 may mirror the current flowing through the first terminal.

The previously set third reference voltage Vref3 may maintain a constant voltage in spite of a temperature change.

The non-inversion terminal and the inversion terminal of the operating amplifier 110 may be virtually grounded and maintain the same electric potential, and thus a feedback voltage may be the previously set third reference voltage Vref3. Thus, current I1 flowing through the feedback resistor 120 may be determined by the previously set third reference voltage Vref3 and the feedback resistor 120, and current I1 flowing through the feedback resistor 120 may be the same as Vref3/Rfb.

A resistance value of the feedback resistor 120 may vary with respect to temperature. More specifically, the resistance value of the feedback resistor 120 may decrease at a uniform rate according to a temperature rise and conversely may increase at a uniform rate according to the temperature rise.

The feedback resistor 120 having the resistance value decreasing according to the temperature rise may include a Poly resistor. The feedback resistor 120 having the resistance value increasing according to the temperature rise may include an Nwell resistor. However, the feedback resistor 120 is not limited thereto, and may include a resistor having a resistance value varying according to the temperature rise or fall.

The current induction unit 130 may induce the current flowing through the feedback resistor 120 to the first terminal. More specifically, referring to FIG. 3, the current induction unit 130 may be an NMOS transistor including a gate terminal connected to an output terminal of the operating amplifier 110, a source terminal connected to the inversion terminal of the operating amplifier 110, and a drain terminal connected to the current mirroring unit 140. The first terminal may be the drain terminal.

Current flowing through the source terminal of the NMOS transistor may be the same as the current I1 flowing through the feedback resistor 120, and may be the same as current flowing through the drain terminal of the NMOS transistor. Thus, the NMOS transistor may induce the current flowing through the feedback resistor 120 to the drain terminal.

The current mirroring unit 140 may be connected to the drain terminal and mirror the current flowing through the drain terminal. Mirrored current I may be used to charge the above-described capacitor 200, as an output of the current generation unit 100.

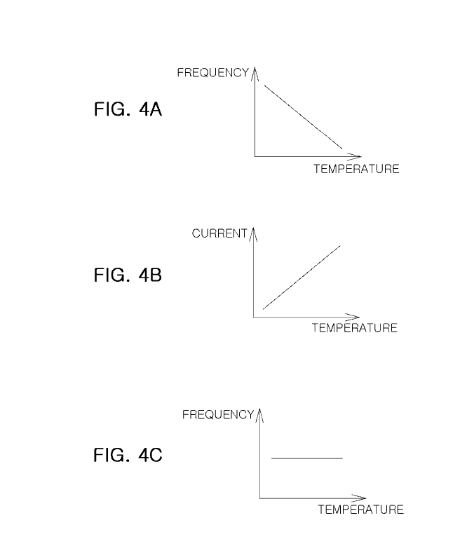

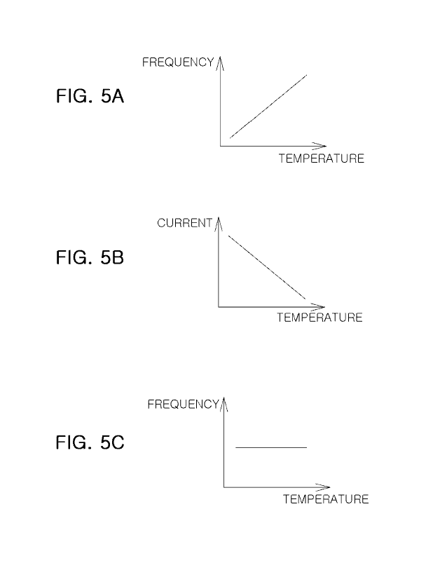

FIGS. 4A through 5C are graphs for explaining a frequency generation method performed by a frequency generation apparatus according to embodiments of the present invention.

FIG. 4A is a frequency graph for explaining a case in which a frequency of an output signal of the frequency generation apparatus decreases according to a temperature rise. FIG. 4B is a current graph of the current generation unit 100 having an amount of current therein increasing according to the temperature rise. FIG. 4C is a graph of a uniform frequency waveform output by complementing the frequency of the output signal decreasing according to the temperature rise by the current generation unit 100 having the amount of current increasing according to the temperature rise.

Referring to FIGS. 4A through 4C, in the case in which the frequency of the output signal of the frequency generation apparatus decreases according to the temperature rise, the current generation unit 100 having the amount of current increasing according to the temperature rise charges the capacitor 200 and thus a frequency variation may be complemented.

In this case, since the current generation unit 100 needs to increase the amount of current according to the temperature rise, the feedback resistor 120 that is an element of the current generation unit 100 may use a resistor having a resistance value decreasing according to the temperature rise.

FIG. 5A is a frequency graph for explaining a case in which the frequency of the output signal of the frequency generation apparatus increases according to a temperature rise. FIG. 5B is a current graph of the current generation unit 100 having an amount of current decreasing according to the temperature rise. FIG. 5C is a graph of a uniform frequency waveform output by complementing the frequency of the output signal increasing according to the temperature rise by the current generation unit 100 having the amount of current decreasing according to the temperature rise.

Referring to FIGS. 5A through 5C, in the case in which the frequency of the output signal of the frequency generation apparatus increases according to the temperature rise, the current generation unit 100 having the amount of current decreasing according to the temperature rise charges the capacitor 200 and thus a frequency variation may be complemented.

In this case, since the current generation unit 100 needs to decrease the amount of current according to the temperature rise, the feedback resistor 120 that is an element of the current generation unit 100 may use a resistor having a resistance value increasing according to the temperature rise.

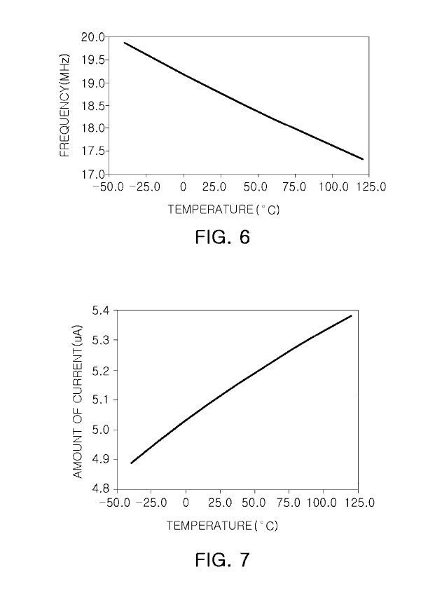

FIGS. 6 through 8 are graphs of simulation results of a frequency generation apparatus according to embodiments of the present invention.

FIG. 6 is a graph for explaining a frequency variation of an output signal of a general frequency generation apparatus with respect to a temperature change. Referring to FIG. 6, a frequency of the output signal decreases according to a temperature rise. More specifically, in a case in which a temperature changes from about −40° C. to about 125° C., the frequency varies from about 19.6 MHz to about 17.6 MHz.

FIG. 7 is a graph for explaining a change in an amount of current of the current generation unit 100 according to the temperature change, and shows a simulation result using a Poly resistor having a temperature coefficient of −1000 ppm/° C. as the feedback resistor 120.

Referring to FIG. 7, the amount of current of the current generation unit 100 increases according to a temperature rise. More specifically, in a case in which the temperature changes from about −40° C. to about 125° C., the amount of current varies from about 48.4 uA to about 53.8 uA.

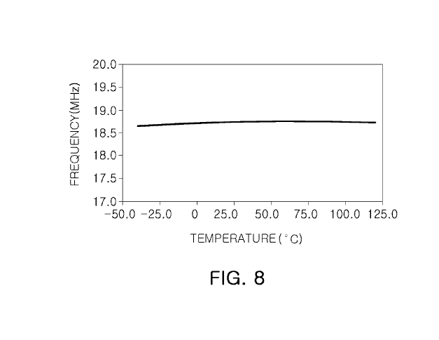

FIG. 8 shows a simulation result obtained by complementing the frequency of the output signal of the general frequency generation apparatus of FIG. 6 by using the current generation unit 100 of FIG. 7.

Referring to FIG. 8, in a case in which the temperature changes from about −40° C. to about 125° C., the frequency of the output signal in FIG. 8 varies from about 18.55 MHz to about 18.65 MHz.

That is, the frequency varies from 18.6 MHz±1 MHz in FIG. 6, whereas the frequency varies to 18.6 MHz±0.005 MHz in FIG. 8. In a case in which the current generation unit 100 that varies an amount of current according to a temperature complements the frequency variation with respect to the temperature change, a uniform frequency of about 50 times may be obtained.

As set forth above, according to embodiments of the invention, a constant frequency may be generated by complementing a frequency variation in which frequency rises or falls with respect to a temperature change by using a current source having an amount of current varying with respect to the temperature change.

Further, a frequency generation apparatus and a frequency generation method capable of generating a constant frequency in spite of a temperature change without additional circuit and device are provided.

While the present invention has been shown and described in connection with the embodiments, it will be apparent to those skilled in the art that modifications and variations can be made without departing from the spirit and scope of the invention as defined by the appended claims.

What is claimed is:

1. A frequency generation apparatus comprising:
a current generation unit varying an amount of current with respect to a temperature change;
a capacitor charged with charges by the current generation unit;
a discharge circuit unit comparing a charging voltage of the capacitor with a previously set first reference voltage and discharging the capacitor; and
an output signal generation unit comparing the charging voltage of the capacitor with a previously set second reference voltage and generating an output signal,
wherein the current generation unit varies the amount of current so as to maintain a constant frequency in the output signal.

2. The frequency generation apparatus of claim 1, wherein the current generation unit varies the amount of current with respect to the temperature change so as to complement a frequency variation in a case in which a frequency of the output signal varies with respect to the temperature change.

3. The frequency generation apparatus of claim 2, wherein the current generation unit increases the amount of current according to a temperature rise so as to complement the frequency variation in a case in which the frequency of the output signal decreases according to the temperature rise.

4. The frequency generation apparatus of claim 2, wherein the current generation unit decreases the amount of current according to the temperature rise so as to complement the frequency variation in a case in which the frequency of the output signal increases according to the temperature rise.

5. The frequency generation apparatus of claim 1, wherein the current generation unit includes:
an operating amplifier including a non-inversion terminal to which a previously set third reference voltage is applied and an inversion terminal to which a feedback voltage is applied;
a feedback resistor connected between the inversion terminal and a ground and detecting the feedback voltage;
a current induction unit inducing current flowing through the feedback resistor to a first terminal; and
a current mirroring unit mirroring the current flowing through the first terminal.

6. The frequency generation apparatus of claim 5, wherein the current induction unit is an NMOS transistor including:
a gate terminal connected to an output terminal of the operating amplifier;
a source terminal connected to the inversion terminal of the operating amplifier; and
a drain terminal connected to the current mirroring unit.

7. The frequency generation apparatus of claim 5, wherein a resistance value of the feedback resistor varies with respect to temperature.

8. The frequency generation apparatus of claim 7, wherein the feedback resistor includes one of a Poly resistor having a resistance value decreasing according to the temperature rise and an Nwell resistor having a resistance value increasing according to the temperature rise.

9. The frequency generation apparatus of claim 5, wherein the third reference voltage maintains a uniform voltage value in spite of the temperature change.

10. A frequency generation method comprising:
generating a triangular wave by a current generation unit charging a capacitor and a discharge circuit unit discharging the capacitor;
comparing the triangular wave with a previously set second reference voltage and generating an output signal; and
varying an amount of current of the current generation unit so as to maintain a constant frequency in the output signal.

11. The frequency generation method of claim 10, wherein in the varying of the amount of current, the amount of current varies with respect to a temperature change so as to complement a frequency variation in a case in which the frequency of the output signal varies with respect to the temperature change.

12. The frequency generation method of claim 10, wherein in the varying of the amount of current, the amount of current increases according to a temperature rise so as to complement the frequency variation in a case in which the frequency of the output signal decreases according to the temperature rise.

13. The frequency generation method of claim 10, wherein in the varying of the amount of current, the amount of current decreases according to the temperature rise so as to complement the frequency variation in a case in which the frequency of the output signal increases according to the temperature rise.

14. The frequency generation method of claim 10, wherein in the varying of the amount of current, an amount of the current flowing through a feedback resistor to which a previously set third reference voltage is applied varies with respect to temperature.

15. The frequency generation method of claim 14, wherein a resistance value of the feedback resistor varies with respect to the temperature.

16. The frequency generation method of claim 14, wherein the feedback resistor includes one of a Poly resistor having a resistance value decreasing according to the temperature rise and an Nwell resistor having a resistance value increasing according to the temperature rise.

17. The frequency generation method of claim 16, wherein the third reference voltage maintains a uniform voltage value in spite of the temperature change.
